(19) United States
(12) Patent Application Publication
(10) Pub. No.: US 2010/0052586 A1
(43) Pub. Date: Mar. 4, 2010

(54) DETECTOR CIRCUIT

(76) Inventors: Wolfgang Krauth, Achern-Sasbachried (DE); Gerhard Knecht, Iffezheim (DE)

Correspondence Address: RONALD E. GREIGG;GREIGG & GREIGG P.L.L.C., 1423 POWHATAN STREET, UNIT ONE, ALEXANDRIA, VA, 22314, US

(21) Appl. No.: 12/517,097

(22) PCT Filed: Oct. 16, 2007
(86) PCT No.: PCT/EP2007/061011

§ 371 Date: Jun. 1, 2009

(30) Foreign Application Priority Data
Dec. 1, 2006 (DE) 102006056852.4

(51) Int. Cl. H02P 6/18; H03K 5/153

(52) U.S. Cl. 318/400.32; 327/77

(57) ABSTRACT

The invention relates to a detector circuit for detecting a change in voltage at a terminal or node with respect to a reference potential. The detector circuit comprises an electronic switch with a control terminal, which has a predetermined switching potential at which the switch operates, and with a detection signal output for outputting a detection signal, and a voltage matching circuit, which provides a control potential at the control terminal of the switch which corresponds to a potential of the terminal which has changed by a predetermined, fixed potential absolute value. The predetermined fixed potential absolute value is selected in such a way that the control potential corresponds to the switching potential or approximately to the switching potential when the reference voltage is applied to the terminal in such a way that the change in voltage to be detected causes the switching potential of the electronic switch to be exceeded or undershot.

The invention relates to detector circuits, in particular for detecting a voltage change at a coil winding of a drive coil of an electric motor.

In EC motors with sensorless commutation, the rotor position is detected by monitoring the voltage at individual coil windings and, from a voltage change at a non-triggered coil winding, ascertaining the instant at which a magnet pole moving past the coil winding induces a voltage.

Typically, a first terminal of a coil winding is solidly connected to a first supply voltage potential, as is the case for instance with an M circuit of coil windings of an electric motor. A second terminal of the coil winding is connected to a second supply voltage potential via a triggerable transistor. In the non-triggered state, the second terminal is connected to the supply voltage potential only via the coil winding. As soon as the coil winding moves across a magnet pole, however, a voltage is induced that causes a voltage change with regard to the supply voltage potential. The voltage change is detected, and a detection signal is generated which is used to determine the rotor position. Depending on the rotor position determined, the commutation of the electric motor is performed.

Usually, for detecting the voltage change via a coil winding, the potential at the second terminal of the coil winding is reduced by a voltage divider and compared, for instance with the aid of a differential amplifier, comparator, and the like, with a threshold voltage generated from the supply voltage, for instance via a further voltage divider, in order to detect the instant of the voltage change to be detected at the motor winding.

The use of voltage dividers is necessary, since in the example described, the voltage change is effected in the range of the supply voltage potential, which is typically outside the common mode rejection range of the differential amplifier. When voltage dividers are used, however, the tolerances of the resistors used for the voltage dividers have a considerable influence on the comparison voltage generated, especially if the division ratio is high. This lessens the precision with which the instant of the zero crossover or the pole change of the electric motor can be determined and thus reduces the efficiency of the commutation.

It is the object of the present invention to reduce the sensitivity of the detector circuit with regard to component tolerances, so that the instant of the voltage change can be detected more precisely, and so that when the detector circuit is used in a motor control system, the efficiency of triggering an electric motor with sensorless commutation can be increased.

These objects are attained by the detector circuit as defined by claim 1 as well as by the motor control system and the electric motor system of the coordinate claims.

Further advantageous features of the invention are defined by the dependent claims.

In a first aspect, a detector circuit for detecting a voltage change at a terminal relative to a reference potential is provided. The detector circuit includes an electronic switch, having a control terminal which has a predetermined switching potential at which the switch switches, and having a detection signal output for outputting a detection signal. Furthermore, a voltage adaptation circuit is provided, which furnishes a control potential to the control terminal of the switch that corresponds to a potential of the terminal varied by a predetermined fixed potential amount. The predetermined fixed potential amount is selected such that the control potential, upon application of the reference voltage to the terminal, is equivalent to the switching potential or approximately equivalent to the switching potential, such that the voltage change to be detected causes overshooting or undershooting of the switching potential of the electronic switch.

The detector circuit makes it possible for a voltage change at a terminal, whose potential may also be outside the supply voltage of the detector circuit, to be detected and output as an edge of the detection signal. Moreover, by the use of the voltage adaptation circuit, which varies the voltage to be detected by a fixed (essentially absolute) potential amount to the switching threshold of the electronic switch, the influence of resistor tolerances is reduced.

Furthermore, the voltage adaptation circuit can be embodied with a diode which is connected directly to the terminal and to the control terminal of the electronic switch, and the predetermined voltage amount is equivalent to the diode voltage or the breakdown voltage of the diode that drops across the diode.

In a further embodiment, the electronic switch is embodied as a transistor circuit, having a first transistor whose base terminal is equivalent to the control terminal and whose base-to-emitter voltage, upon application of the reference voltage to the terminal, is set essentially to the diode voltage of a base-to-emitter transition of the first transistor, so that the first transistor is still barely conducting, and the voltage adaptation circuit is embodied such that the base-to-emitter voltage, upon the occurrence of the voltage change to be detected, drops below the diode voltage, so that the first transistor changes over to the blocking state.

Furthermore, the reference voltage can be equivalent to a supply voltage potential, and the emitter terminal of the first transistor can be connected directly to the supply voltage potential, so that the switching potential is fixed as the supply voltage potential, varied by the diode voltage of the base-to-emitter transition.

It may be provided that the voltage adaptation circuit includes a second transistor, whose collector terminal and base terminal are short-circuited and connected to the base terminal of the first transistor, so that between the emitter terminal and the collector terminal of the second transistor, a diode voltage of the base-to-emitter transition of the second transistor is established.

Preferably, the first transistor and the second transistor are embodied as identical transistors, and the emitter terminal of the second transistor is connected to the terminal via a pickup resistor, and the collector terminal of the second transistor is connected to a further supply voltage potential via a further resistor, and the resistance ratio between the pickup resistor and the further resistor amounts to a maximum of 1:50.

In particular, the first transistor and the second transistor are embodied as double transistors in integrated form.

In a further aspect, a motor controller for triggering m electric motor with a trigger signal is provided. The motor controller includes a detector circuit for outputting a detection signal that indicates an inductive voltage change of a coil winding of the electric motor, and a commutator circuit for commuting the coil winding of the electric motor as a function of the detection signal.

In a further aspect, an electric motor system is provided, having a motor controller and having all electric motor with at least one coil winding, the coil winding being solidly connected to a supply voltage potential by a first terminal and the terminal of the detector circuit is connected to the second terminal of the coil winding, in order during operation of the motor to detect a voltage induced in the coil winding.

A preferred embodiment of the invention will be described in further detail below in conjunction with the accompanying drawings. They show:

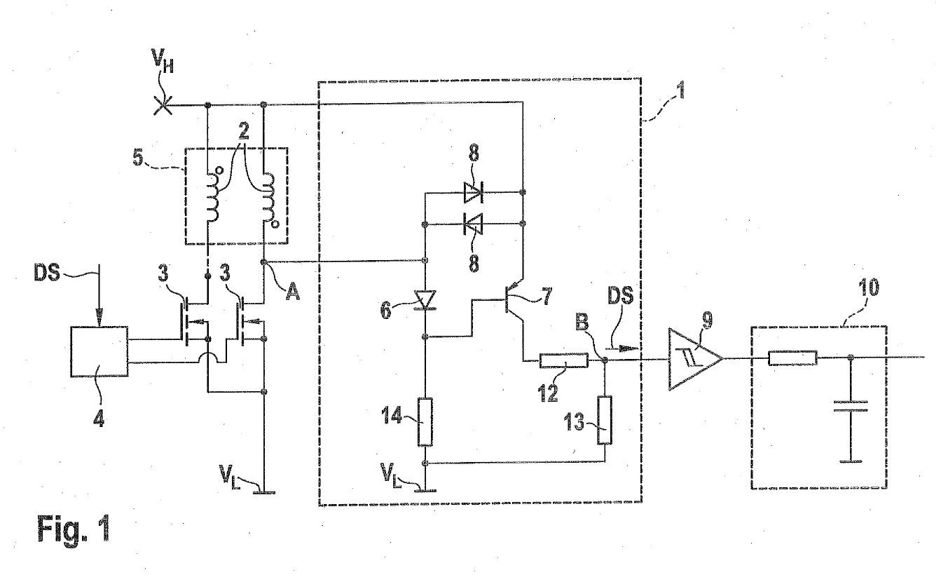

FIG. 1, a circuit diagram of a motor control circuit having a detector circuit in accordance with a first embodiment of the invention; and

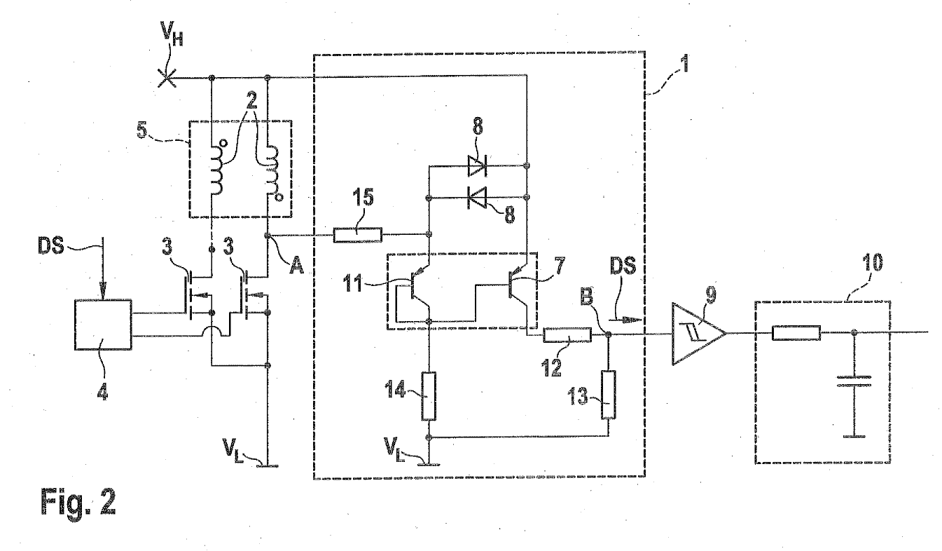

FIG. 2, a circuit diagram of a motor control circuit having a detector circuit in accordance with a further embodiment of the invention.

FIG. 1 shows a circuit diagram of a motor control circuit having a detector circuit 1 in accordance with a first embodiment of the invention. The detector circuit 1 is connected to a coil winding 2 of a drive coil 5 of an electric motor (not shown), in order to pick up a potential. For the sake of simplicity, only one drive coil of the electric motor is shown, which is embodied in bifilar form with two oppositely wound coil windings. Each coil winding 2 is driven via its own switching transistor 3, which is connected in series with the coil winding 2 and is triggered by a commutator circuit 4 for driving the motor with an applicable trigger signal, for instance with the aid of pulse width modulated trigger signals. The commutation, that is, switching the coil windings 2 of the drive coil of the electric motor on and off, is effected as a function of the rotor position, the rpm of the electric motor, and other parameters.

In sensorless electric motors, ascertaining the rotor position is done by detecting a voltage change in at least one of the coil windings that is caused by induction because of a relative motion between the coil winding and the magnet pole. In the motor topology described above, as in an M circuit, all the coil windings 2 are connected by their first terminals to a high supply potential V_{H}. An induced voltage can then be detected as a potential change at a second terminal of the coil winding 2, if the applicable coil winding 2 is not triggered by the commutator circuit 4 via the corresponding switching transistor. The term “potential” is understood here as the voltage potential at a node, while the term “voltage” means the potential difference between two nodes.

The nucleus of the detector circuit 1 is a transistor circuit, with a transistor 7 and with the collector resistors 12 and 13, which are wired in the form of an emitter circuit. In detail, this means that the emitter of the transistor 7, which is embodied as a PNP transistor, is connected to the high supply voltage potential V_{H}, and the collector of the transistor 7 is connected to a low supply voltage potential V_{L} via a series circuit of the collector resistors 12 and 13.

The emitter circuit is operated as an electronic switch, which is controlled via the base terminal of the transistor 7. In a noninduction situation, in which no voltage is induced in the coil winding 2, a control potential is applied to the base terminal of the transistor 7 and drives the transistor 7 to or just above the switching threshold. In other words, in the noninduction situation, the transistor 7 is just barely conducting or of low impedance or of markedly lower impedance than in the blocked state.

The control potential is generated from the potential at a node A, which corresponds to the second terminal of the coil winding 2, and a diode 6. The diode 6 is connected in series with a further resistor 14 between the node A and the low supply voltage potential V_{L}. The further resistor 14 makes it possible for a voltage drop at the level of the diode voltage to develop across the diode 6. At the cathode of the diode 6, that is, at the node between the diode 6 and the further resistor 14, the control potential is picked up. The diode 6 is dimensioned such that as the control potential, a potential is established at which the transistor 7 is barely just switched through or in other words conducting. If a voltage is now induced in the coil winding 2, which causes the potential at the node A to rise, then the control potential at the base terminal of the transistor 7 also rises, since the control potential essentially represents the potential of the second terminal of the coil winding 2, reduced by the diode voltage of the diode 6. Even a minimal increase in the control potential at the control potential of the transistor 7, however, causes the transistor 7 to change from a lower-impedance state to a blocking state. Instead of the conventional diode 6, a Zener diode in the blocking mode may also be provided, for reducing the potential at the terminal A by the breakdown voltage, so that the most precise possible adaptation of the control potential to the switching threshold can be made.

As already described above, the collector terminal of the transistor 7 is connected to the low supply voltage potential V_{L} via a series circuit of two collector resistors 12 and 13. At a node B between the two collector resistors 12, 13, a detection signal DS can be picked up, as the output of the detector circuit, and this signal as described above detects the occurrence of a voltage increase in the coil winding 2 caused by an induction, because in the case of an induction a voltage drop is detectable. At a voltage rise at the node A, a trailing edge at the node B results as the detection signal DS.

The detection signal DS can now be connected to one input of a Schmitt trigger 9 or alternatively a comparator and the like, in order to further increase the steepness of the edge and to reduce interference signal effects, for instance from crosstalk of the trigger signal and the detection signal DS. One output of the Schmitt trigger 9 can also be connected to a filter circuit 10, to eliminate interference effects from the clocking of the phase voltages through the commutator circuit 4. The filter 10 is embodied as a low-pass filter, since the frequency of the voltage inductions into the coil windings is markedly lower than the frequency with which the phase voltages are triggered by the commutator circuit 4.

The provision of the collector resistors 12 and 13 makes it possible to put the output voltage of the emitter circuit into a potential range in which the Schmitt trigger 9 is sensitive. In one exemplary embodiment, the supply voltage of the electric motor (V_{H}-V_{L}) can be 12 V, and a standard component, which requires a supply voltage of 5 V, for instance, can be used as the Schmitt trigger 9. Thus the Schmitt trigger 9 is sensitive only within a voltage range between 0 and 5 V (for instance at approximately 2.5 V), so that with the aid of the collector resistors 12 and 13, the output voltage of the emitter circuit can be put into a working range of the Schmitt trigger 9.

For instance, if the supply voltage of the electric motor and of the entire voltage detector circuit is equivalent to a supply voltage of the Schmitt trigger 9, then instead of the collector resistors 12 and 13, only a single collector resistor may for instance be used between the collector terminal of the transistor 7 and the low supply voltage potential V_{L}; that output of the emitter circuit in this case can be picked up directly at the collector of the transistor 7.

Optionally, for protection of the detector circuit 1, two parallel, oppositely switched recovery diodes 8 may be provided, which are provided between the second terminal of the coil winding 2 and the high supply voltage potential V_{H}, so that in this way an induced voltage in the coil winding 2 whose amount is greater than the diode voltage can be limited by the applicable recovery diode 8 in both the positive and the negative direction compared to the high supply voltage potential V_{H}.

In FIG. 2, a further embodiment of the invention is shown. In it, the same reference numerals identify elements of the same or comparable function.

Since it is difficult in practice, for instance when using discrete components, to select the diode 6 such that the transistor 7 is operated close to its switching threshold or directly at its switching threshold, instead of the diode 6 a further transistor 11, identical to the transistor 7, may be provided. In such a case, the identical further transistor 11 is switched as a diode; that is, its base terminal is connected directly to its collector terminal. The diode voltage of the further transistor 11 switched as a diode and the voltage of the switching threshold of the transistor 7 are thus virtually identical.

In order in the noninduction situation to operate the transistor 7 in the conducting or low-impedance state, a pickup resistor 15 and the further resistor 14 are provided. The pickup resistor 15 is disposed, preferably directly, between the node A, that is, the second terminal of the coil winding 2, and the emitter terminal of the further transistor 11, and the further resistor 14 is disposed between the collector terminal of the further transistor 11 and the low supply voltage potential V_{L}. A flow of current from the node A via the pickup resistor 15, the further transistor 11, and the further resistor 14 to the low supply voltage potential V_{L} causes a voltage drop across the pickup resistor 15, so that the control potential that is applied to the base terminal of the transistor 7 is lowered to such an extent that the transistor 7 is in the ON state. In order not to impair the sensitivity of the voltage detector circuit 1 as a result such that the control potential in the noninduction situation is too far away from the actual switching potential of the transistor 7, the ratio of the pickup resistor 15 to the further resistor 14 is preferably quite low, that is, 1:50 and less, and in particular 1:100. Preferred values as examples for the pickup resistor 15 are in the range from 1 kOhm to 10 kOhm and for the further resistor R2 in the range from 100 kOhm to 500 kOhm.

The voltage divider comprising the collector resistors 12 and 13 adapts the low measurement range of a downstream comparator or Schmitt trigger 9. Preferably, however, the total resistance of the collector resistors 12, 13 is selected to be high, since by that means the amplification of he emitter circuit formed with the transistor 7 is increased.

To assure that the diode voltages of the base-to-emitter transition of the transistors 7 and 11 are as identical as possible, the transistors for the detector circuit 1 are preferably embodied as a double transistor, with the two transistors 7, 11 being embodied jointly integrated, so that they are essentially structurally identical, and thermal effects are largely compensated for by the integration.

In the embodiment, the recovery diodes 8 are connected between the emitter terminal of the further transistor 11 and the high supply voltage potential V_{H}.

The detector circuit may also be embodied analogously for detecting a voltage decrease relative to a low supply voltage potential, by being embodied inversely with an NPN transistor circuit and by transposing the high and low supply voltage potentials. As the voltage adaptation element for adapting the potential at the terminal A, a direct voltage source may also be used, for instance in the form of a battery and the like.

The detector circuit 1 generates a detection signal DS, which, optionally filtered by the Schmitt trigger 9 and the low-pass filter 10, is delivered to the commutator circuit 4, which evaluates the detection signal and from that can determine the rotor position, the rpm of the motor, and other relevant variables.

1-10. (canceled)

11. A detector circuit for detecting a voltage change at a terminal relative to a reference potential, including:
an electronic switch, having a control terminal which has a predetermined switching potential at which the switch switches, and having a detection signal output for outputting a detection signal; and
a voltage adaptation circuit, which furnishes a control potential to the control terminal of the switch that corresponds to a potential of the terminal varied by a predetermined fixed potential amount,
wherein the predetermined fixed potential amount is selected such that the control potential, upon application of the reference voltage to the terminal, is equivalent to the switching potential or approximately equivalent to the switching potential, such that the voltage change to be detected causes overshooting or undershooting of the switching potential of the electronic switch.

12. The detector circuit as defined by claim 11, wherein the voltage adaptation circuit is embodied with a diode which is connected directly to the terminal and to the control terminal of the electronic switch, and the predetermined voltage amount is equivalent to the diode voltage or the breakdown voltage of the diode that drops across the diode.

13. The detector circuit as defined by claim 11, wherein the electronic switch is embodied as a transistor circuit, having a first transistor whose base terminal is equivalent to the control terminal and whose base-to-emitter voltage, upon application of the reference voltage to the terminal, is set essentially to the diode voltage of a base-to-emitter transition of the first transistor, so that the first transistor is still barely conducting, and the voltage adaptation circuit is embodied such that the base-to-emitter voltage, upon the occurrence of the voltage change to be detected, drops below the diode voltage, so that the first transistor changes over to the blocking state.

14. The detector circuit as defined by claim 12, wherein the reference voltage is equivalent to a supply voltage potential, and an emitter terminal of the first transistor is connected directly to the supply voltage potential, so that the switching potential is fixed as the supply voltage potential, varied by the diode voltage of the base-to-emitter transition.

15. The detector circuit as defined by claim 13, wherein the voltage adaptation circuit includes a second transistor, whose collector terminal and base terminal are short-circuited and connected to the base terminal of the first transistor, so that between an emitter terminal and the collector terminal of the second transistor, a diode voltage of the base-to-emitter transition of the second transistor is established.

16. The detector circuit as defined by claim 14, wherein the voltage adaptation circuit includes a second transistor, whose collector terminal and base terminal are short-circuited and connected to the base terminal of the first transistor, so that between an emitter terminal and the collector terminal of the second transistor, a diode voltage of the base-to-emitter transition of the second transistor is established.

17. The detector circuit as defined by claim 15, wherein the first transistor and the second transistor are embodied as identical transistors, and the emitter terminal of the second transistor is connected to the terminal via a pickup resistor, and the collector terminal of the second transistor is connected to a further supply voltage potential via a further resistor, and the resistance ratio between the pickup resistor and the further resistor amounts to a maximum of 1:50.

18. The detector circuit as defined by claim 16, wherein the first transistor and the second transistor are embodied as identical transistors, and the emitter terminal of the second transistor is connected to the terminal via a pickup resistor, and the collector terminal of the second transistor is connected to a further supply voltage potential via a further resistor, and the resistance ratio between the pickup resistor and the further resistor amounts to a maximum of 1:50.

19. The detector circuit as defined by claim 17, wherein the first transistor and the second transistor are embodied as double transistors in integrated form.

20. The detector circuit as defined by claim 18, wherein the first transistor and the second transistor are embodied as double transistors in integrated form.

21. A motor controller for triggering an electric motor with a trigger signal, including:
a detector circuit as defined by claim 11, for outputting a detection signal that indicates an inductive voltage change of a coil winding of the electric motor; and
a commutator circuit for commuting the coil winding of the electric motor as a function of the detection signal.

22. A motor controller for triggering an electric motor with a trigger signal, including:
a detector circuit as defined by claim 12, for outputting a detection signal that indicates an inductive voltage change of a coil winding of the electric motor; and
a commutator circuit for commuting the coil winding of the electric motor as a function of the detection signal.

23. A motor controller for triggering an electric motor with a trigger signal, including:
a detector circuit as defined by claim 13, for outputting a detection signal that indicates an inductive voltage change of a coil winding of the electric motor; and
a commutator circuit for commuting the coil winding of the electric motor as a function of the detection signal.

24. A motor controller for triggering an electric motor with a trigger signal, including:
a detector circuit as defined by claim 14, for outputting a detection signal that indicates an inductive voltage change of a coil winding of the electric motor; and
a commutator circuit for commuting the coil winding of the electric motor as a function of the detection signal.

25. The motor controller as defined by claim 21, wherein at least one of the following elements is provided:
a Schmitt trigger for receiving the detection signal and for filtering interference out of the detection signal; and/or
a low-pass filter for filtering interference signals, occurring in the detection signal, at frequencies of the trigger signal generated by the commutator circuit.

26. The motor controller as defined by claim 22, wherein at least one of the following elements is provided;
a Schmitt trigger for receiving the detection signal and for filtering interference out of the detection signal; and/or
a low-pass filter for filtering interference signals, occurring in the detection signal, at frequencies of the trigger signal generated by the commutator circuit.

27. The motor controller as defined by claim 23, wherein at least one of the following elements is provided:
a Schmitt trigger for receiving the detection signal and for filtering interference out of the detection signal; and/or
a low-pass filter for filtering interference signals, occurring in the detection signal, at frequencies of the trigger signal generated by the commutator circuit.

28. An electric motor system, including:
a motor controller as defined by claim 21; and
an electric motor having at least one coil winding, the coil winding being solidly connected to a supply voltage potential by a first terminal and the terminal of the detector circuit is connected to the second terminal of the coil winding, in order during motor operation to detect a voltage induced in the coil winding.

29. An electric motor system, including:
a motor controller as defined by claim 24; and
an electric motor having at least one coil winding, the coil winding being solidly connected to a supply voltage potential by a first terminal and the terminal of the detector circuit is connected to the second terminal of the coil winding, in order during motor operation to detect a voltage induced in the coil winding.

30. An electric motor system, including:
a motor controller as defined by claim 25; and
an electric motor having at least one coil winding, the coil winding being solidly connected to a supply voltage potential by a first terminal and the terminal of the detector circuit is connected to the second terminal of the coil winding, in order during motor operation to detect a voltage induced in the coil winding.
